(19) United States
(12) Patent Application Publication
(10) Pub. No.: US 2007/0177362 A1
(43) Pub. Date: Aug. 2, 2007

(54) COVERT INTELLIGENT NETWORKED SENSORS AND OTHER FULLY ENCAPSULATED CIRCUITS

(76) Inventor: Frederick O. Fortson, Whitmore Lake, MI (US)

Correspondence Address: GIFFORD, KRASS, SPRINKLE,ANDERSON & CITKOWSKI, P.C, PO BOX 7021, TROY, MI, 48007-7021, US

(21) Appl. No.: 11/669,504

(22) Filed: Jan. 31, 2007

Related U.S. Application Data
(60) Provisional application No. 60/763,551, filed on Jan. 31, 2006.

(51) Int. Cl. H01L 23/28; H05K 5/00

(52) U.S. Cl. 361/752; 174/521

(57) ABSTRACT

A metallic enclosure completely encapsulates an embedded electronic system, which may include sensors, wireless communications devices and other circuits. The enclosure is fabricated in layers of material using a solid-state additive consolidation or lamination process forming a true metallurgical bond between the layers during fabrication without melting the material in bulk. A plurality of enclosures may be provided, each encapsulating an electronic circuit including a wireless transmitter or receiver, with the electronic circuits within the enclosures forming a communications network. As such, a sensor may be used to detect an external characteristic, and a wireless transmitter may be activated to communicate information about the characteristic to a remote receiver. The enclosure may use one or more layers of dissimilar material to form an embedded active or passive electrical component such as an antenna, waveguide, or other device that cooperates with the circuitry.

### REFERENCE TO RELATED APPLICATION

This application claims priority from U.S. Provisional Patent Application Ser. No. 60/763,551, filed Jan. 31, 2006, the entire content of which is incorporated herein by reference.

### FIELD OF THE INVENTION

This invention relates generally to electronic sensing and communications and, in particular, to the use of solid-state consolidation or lamination processes to encapsulate electronic components associated with electronic sensing and communications.

### BACKGROUND OF THE INVENTION

New technologies in wireless networking, radio frequency identification, and sensors provide the potential for a ubiquitous, three-dimensional networked intelligence embedded in products, systems and applications at every level. However, such ubiquitous use of remote sensors has been limited by factors that include high power consumption, hard-wired communications requirements, obtrusive size and weight, installation difficulties, cumbersome operating requirements, limited operational lifetime, and lack of intelligence within the sensor itself. Further barriers are such issues as cost, and resistance to impact, corrosion, thermal cycling etc. which are not addressed by enclosure of such devices in paper or plastic media. In addition, for many critical applications (i.e., in vehicles, on pipelines, in manufacturing systems, etc.) a sensor must be embedded directly in a component or on it using a metallic medium compatible with the engineering design intent materials involved in order to provide functionality.

The problem of embedding sensor, actuator, wireless communication device, electrical power supply or battery, etc., within a metallic part in a homogeneous, metallurgically uniform and structurally sound way without damage to the very sensitive devices is formidable. Conventional techniques include casting, welding, mechanical fastening and brazing. Each of these presents difficulties. If it is desired to cast electronics into a component, only the lowest melting-point alloys such as Woods metal may be used without damage to the electrical systems. Even then, dissolution of the device in the molten metal may be an issue; even a salt (which melts at temperatures well above 400 degrees), can be dissolved in water at a much lower temperature.

If the metallic medium is to be welded around the electronics, the presence of high local temperatures, molten metal, and very large electromagnetic disturbances associated with the weld arc which may damage sensitive electronic components must be considered. In mechanical fastening, the electrical components are sealed using multiple mechanical components that are fastened together using screws, cinches, etc. These encasements tend to leak and more complex from an assembly standpoint. In the case of brazing, the entire component must be uniformly elevated to a high temperature (which depends on the melting point of the braze alloy involved, but which by definition involves temperatures in excess of 450C-AWS Welding Handbook, vol. 1); again a level sufficient to damage such delicate devices.

### SUMMARY OF THE INVENTION

This invention resides in embedded electronic systems, including sensors, wireless communications devices and other circuits. In the preferred embodiments, a metallic enclosure completely encapsulates the circuit, the enclosure being fabricated in layers of material using a solid-state additive consolidation or lamination process forming a true metallurgical bond between the layers during fabrication without melting the material in bulk. Options for the consolidation process include ultrasonic consolidation, electrical resistance welding, frictional welding and cold gas dynamic spraying. Any number of subtractive fabrication processes may be used to achieve a final desired shape, including that of a small, unobtrusive coin.

In addition to sensors and communications circuits such as wireless transmitters and receivers, a plurality of enclosures may be provided, each encapsulating an electronic circuit including a wireless transmitter or receiver, with the electronic circuits within the enclosures forming a communications network. As such, a sensor may be used to detect an external characteristic, and a wireless transmitter may be activated to communicate information about the characteristic to a remote receiver.

The enclosure may use one or more layers of dissimilar material to form an embedded active or passive electrical component such as an antenna, waveguide, or other device that cooperates with the circuitry. To conserve power, the electronic circuit may include an acoustic or radio-frequency detector that activates other components if the sound or RF energy exceeds a predetermined level. One or more elements may also be provided to receive energy from an external source for battery-charging or other purposes. Or a moving magnet or coil may be used to generate electricity to power the electronic circuit.

A method of embedding electronics in a metallic structure according to the invention comprises the steps of providing electronic circuitry; providing a feedstock of material; and completely encapsulating the circuitry in an enclosure by bonding layers of the material around or over the circuitry without an adhesive using a solid-state additive consolidation or lamination process that does not melt the material in bulk. The electronic circuitry may be pre-encapsulated in a non-metallic form, with the enclosure being fabricated over the encapsulated electronic circuitry acting as a support structure.

### BRIEF DESCRIPTION OF THE DRAWINGS

FIG. 1 is a drawing in partial cross section depicting a preferred embodiment of the invention;

FIG. 2 is a drawing in partial cross section depicting an alternative construction; and

FIG. 3 illustrates one way in which dissimilar materials may be used to embed passive or active components.

### DETAILED DESCRIPTION OF THE INVENTION

The above-identified problems are overcome through the use of a solid-state consolidation or lamination process, preferably an ultrasonic joining process. The additive means of laminating or depositing the metal layers together may include ultrasonic metal welding, cold gas dynamic spraying, resistance metal welding or friction welding. In the preferred embodiments, a process or processes are used which are capable of constructing a solid metal enclosure from featureless feedstocks at low temperatures without melting the material in bulk without adhesives.

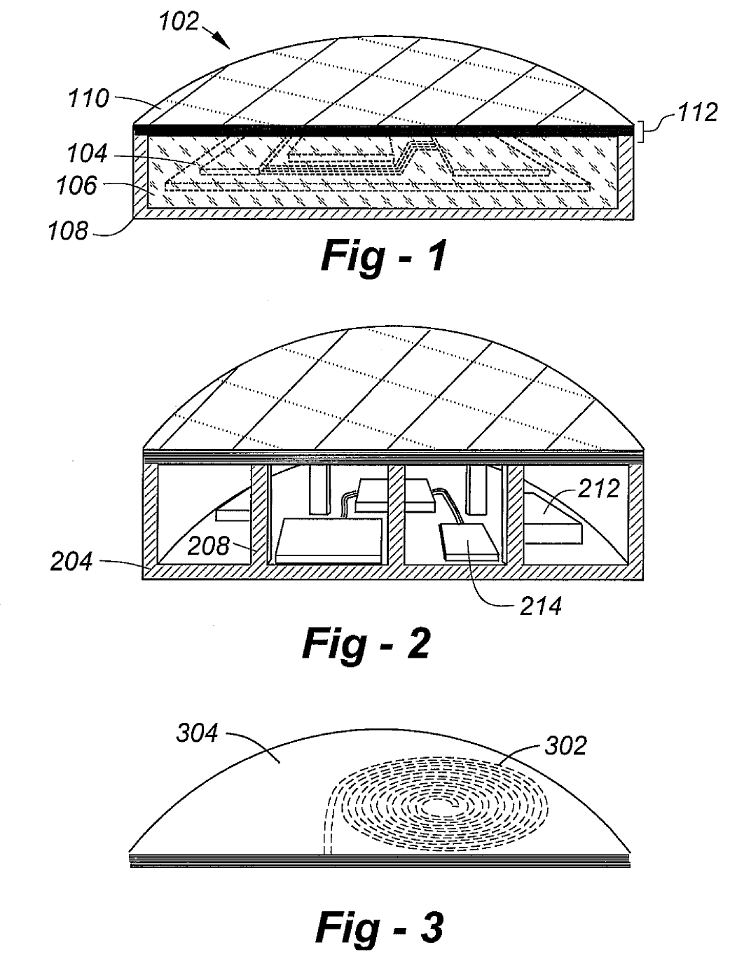

As shown generally at 102 in FIG. 1, the electronic components 104 may be molded into the article during the fabrication process with a non-metallic potting material 106 which is subsequently encased during the remainder of the process. Although an additive process may be used for the entire construction, it is more efficient and economical to use a tray or dish 108 of solid material onto which a ‘lid’ 110 built from layers 112 is applied. In this case the encapsulation of the electronic components acts as a support structure. Although a coin-shaped article is shown being covered with crisscrossing consolidated “tapes,” an advantage of the invention is that any forms may be produced with any appropriate feedstocks. To arrive at a desired final form, subtractive manufacturing steps such as milling, grinding, laser ablation, cutting, turning, ion milling, or other processes may be used. FIG. 2 depicts an alternative construction which is air- or gas-filled. In this configuration, posts or pillars 208 may be disposed around circuits 212, 214 to function as supports.

As disclosed and described in U.S. Pat. Nos. 6,463,349; 6,519,500; 6,685,365; 6,814,823; 6,457,629; and 6,443,352, the entire content of each being incorporated herein by reference, during ultrasonic welding a true metallurgical bond is formed. This process can be used with many engineering alloys in systems as diverse as those based on Al, Fe, Cu, Ni, Ti and many alloy systems based upon these and other elements.

A key advantage offered by ultrasonic consolidation processing is that during this process, which is a solid state, layered metal additive fabrication technique for producing arbitrary geometry from featureless feedstocks, only about 2% of the matrix (i.e., embedding medium) material experiences any temperature elevation, and this for only a few (50-100) msec. This tiny volume may reach a temperature of 0.5 Tm. Since metals have relatively high thermal conductivity, this heat is rapidly dissipated, and the temperature of the overall structure, component, etc. sees little or no change. Thus if electronic devices are embedded in a metal component or assembly using this technique, they will not be damaged by heat, or electromagnetic radiation.

Although embedding electronic devices with a metal object is in itself an important object of this invention, another significant consideration is the production of embedded wireless devices, including transmitters and receivers, allowing for external communications, including network communication and cooperation. Once a device has been embedded within a metallic component, the problem of wirelessly transmitting a signal outside the metal matrix of the device presents further apparently insuperable technical challenges. However, the combination of additive and subtractive methods, or the usage of very tiny additive increments such as droplets, or very fine wires, allows the embedding, or building, in of waveguides within a device.

Laminated ultrasonic joining further enables the bonding of dissimilar metals as part of the object which can by itself serve as a radio-frequency generator. These waveguides and self-emitting packages then eliminate the need for external antennas and allow an electrical signal to be transmitted outside the additively manufactured metal components containing the electronic devices. FIG. 3 illustrates one such configuration, wherein an antenna 302 is embedded directly within the layers of a lid structure 304.

The process disclosed herein may be used with numerous solid-state electronic devices, such as sensors, actuators, power supplies, integrated circuits for computation or data storage, wireless data communication devices, and so forth. The technique may further be used to embed or fabricate a wave guide or antenna via integral additive, subtractive, or combined additive and subtractive processes or other manufacturing techniques such as MEMS-type fabrication.

The wave guide may be an integral feature of the component/electronic device, including a geometry which serves to eliminate the need for antenna to direct a radio or other frequency signal out of the integral component/intelligent active sensing device. A fiber optic, or other non-metallic radio frequency transmitting element may serves as the wave guide between the internal device and the ambient environment.

According to the invention, dissimilar metals having varying electrical conductivity may be placed in intimate contact via a solid-state metal-lamination process in order to produce a current flow for purposes which include but are not limited to the generation of electrical power, temperature measurements, radio-frequency generation, acceleration measurements or other purposes. Dissimilar metals having varying electrical conductivity may be placed in intimate contact via a solid-state metal lamination process in order to produce a current flow for purposes which include but are not limited to radio frequency generation for the purpose of connecting such a device to the internet, an intranet, a sense and control network, an earth orbiting satellite, flocking robotic reconnaissance or other devices.

The invention may be used to provide a DC ground connection for radio frequency noise elimination or reduction as well as protection from electrostatic discharge, lightning strikes, electromagnetic pulse (EMP), and thereby also provide a defense against offensive EMP weapons that employ broad spectrum or narrow spectrum electromagnetic radiation as a primary means of operation. Devices placed according to the invention may radiate electromagnetic energy despite the presence of a DC ground connection to a mounting chassis or other object or wire.

The fabrication of a robust, sturdy metallic enclosure produced according to the invention allows a magnet to be displaced through a coil, producing an electrical current which may be used to charge a battery or capacitor. For example, the magnet may be embedded in a fixed position within the article and an internal coil is placed in relative motion with respect to the magnet, producing an electrical current which charges a battery or capacitor.

The invention may further allow an internally mounted gimbal ring to permit the free incline in any direction of an electromechanical power generation device, producing an electrical current which charges a battery or capacitor. The solid-state consolidation/lamination process may use featureless feedstocks such as tapes, sheets, wires, or droplets, either with or without secondary subtractive processing. The part geometry may furthermore be constructed from layers or components that have been previously fabricated using any available means and have predefined geometries.

The materials used may employ dissimilar metals, piezo-ceramics, thermoelectric, or other techniques to harvest energy from movement of the device, changes in ambient temperatures, acoustic excitation, or other energetic inputs that can be converted into electrical impulses in order to power the device without the requirement for an external power supply, or separate replacement or recharging of a battery. Previous attempts to address these issues typically resulted in improvement of one metric at the expense of another. For example, larger batteries will solve operational lifetime problems as far as power consumption is concerned, but also increase the size and weight of the remote sensing device itself.

Devices fabricated according to the invention will be small and lightweight, and may have a form factor similar to a ‘silver dollar’ in weight and appearance. As such, the devices may be easily carried and dispersed by hand or mechanical means along roads and trails, over earthen berms and embankments, down alleys, into windows and doorways, and deployed in any outdoor or indoor sites that are typical of an urban warfare environment. Certain devices will create their own wireless communication mesh network to pass data and control packets between sensors as needed, and may be remotely commanded to report data and status after operating for extended periods in silent running mode.

The devices may use internal power to activate their embedded smart sensor electronics to perform sensing missions including Audio Signature Analysis. The devices may ‘listen’ to ambient sound and other low-frequency waveforms, perform signal discrimination and then internally record and report the presence and number of passing vehicles, footsteps, voices, gunshots, explosions and other events of interest. Certain devices may be developed to discriminate between the audio signature of a normally laden vehicle and that of a vehicle carrying significant payload, such as an automobile or cart overburdened with Improvised Explosive Devices (IEDs). The devices may also include the capability to measure temperature and to be connected to other sensing devices for data collection and reporting.

Devices constructed in accordance with the invention address issues of concern regarding the design, fabrication, functionality and deployment of remote sensing devices, including:
Embedded Intelligence. Embedding microprocessor based data acquisition, command and control devices directly inside a sealed, bonded metal enclosure provides a weatherproof tamperproof and rugged housing to protect the electronics used in the smart remote sensor
Wireless Connectivity. The process is uniquely able to take advantage of properties inherent in the bonding of dissimilar metals to provide wireless connectivity that uses the enclosure itself to radiate radio frequency and microwave energy, thereby eliminating the need for external antennas. This results in a smaller, lighter, unobtrusive sensor node with greater reliability and ruggedness as compared to designs requiring external antennas and connectors.
Mesh Networking. Sensors according to the invention may be configured to communicate directly with a host node, such as a PC operating in a fleet vehicle, as well as communicate and pass messages among an arbitrary number of inventive sensor nodes to extend the effective range of wireless operation and to propagate command and control packets among themselves autonomously.
Low Power. The sensors utilize proprietary power saving technology to ‘wake up’ and perform their mission only when a sound is detected that exceeds a programmable threshold. The rechargeable, embedded power source ‘steals’ power from nearby electromagnetic sources, sunlight, heat, mechanical vibration. Activation energy by remote microwave frequency command and control devices also is used to recharge the internal power source. The devices should be able to operate up to several months without any external power source.
Stealth. Devices according to the invention are small, lightweight, may be coated in any color combination for camouflage purposes, and can be unobtrusively thrown or placed as needed. The devices require no wired connection to outside infrastructure for power or communications, solving many of the installation problems facing traditional wired and wireless sensor devices.

I claim:

1. An encapsulated electronic system, comprising:
an electronic circuit; and
a metallic enclosure that completely encapsulates the circuit, the enclosure being fabricated in layers of material using a solid-state additive consolidation or lamination process forming a true metallurgical bond between the layers during fabrication without melting the material in bulk.

2. The encapsulated electronic system of claim 1, wherein the enclosure is fabricated using an ultrasonic consolidation process.

3. The encapsulated electronic system of claim 1, wherein the enclosure is fabricated using electrical resistance welding.

4. The encapsulated electronic system of claim 1, wherein the enclosure is fabricated using frictional welding.

5. The encapsulated electronic system of claim 1, wherein the enclosure is fabricated using cold gas dynamic spraying.

6. The encapsulated electronic system of claim 1, further including the use of a subtractive fabrication process to achieve a final desired shape.

7. The encapsulated electronic system of claim 1, wherein the enclosure is coin-shaped.

8. The encapsulated electronic system of claim 1, wherein the electronic circuit includes a sensor.

9. The encapsulated electronic system of claim 1, wherein the electronic circuit includes a wireless transmitter or receiver.

10. The encapsulated electronic system of claim 1, including:
a plurality of enclosures, each encapsulating an electronic circuit including a wireless transmitter or receiver; and
wherein the electronic circuits within the enclosures form a communications network.

11. The encapsulated electronic system of claim 1, wherein the enclosure uses one or more layers of dissimilar material to form an embedded active or passive electrical component.

12. The encapsulated electronic system of claim 1, wherein the enclosure uses one or more layers of dissimilar material to form an embedded antenna.

13. The encapsulated electronic system of claim 1, wherein the enclosure includes an embedded waveguide.

14. The encapsulated electronic system of claim 1, wherein the electronic circuit includes an acoustic or radio-frequency detector that activates other components if the sound or RF energy exceeds a predetermined level.

15. The encapsulated electronic system of claim 1, wherein the electronic circuit includes:
a rechargeable battery; and
one or more elements to receive energy from an external source for battery-charging purposes.

16. The encapsulated electronic system of claim 1, wherein the electronic circuit includes:
a rechargeable battery; and
one or more elements to receive energy from an external source for battery-charging purposes.

17. The encapsulated electronic system of claim 1, wherein the electronic circuit includes:
a sensor to detect an external characteristic; and
a wireless transmitter to communicate information about the characteristic to a remote receiver.

18. The encapsulated electronic system of claim 1, wherein the enclosure includes:
a magnet and a coil, one or both of which move when the enclosure is moved to generate electricity for the electronic circuit.

19. A method of embedding electronics in a metallic structure, comprising the steps of:
providing electronic circuitry;
providing a feedstock of material; and
completely encapsulating the circuitry in an enclosure by bonding layers of the material around or over the circuitry without an adhesive using a solid-state additive consolidation or lamination process that does not melt the material in bulk.

20. The method of claim 19, wherein the enclosure is fabricated using an ultrasonic consolidation process.

21. The method of claim 19, wherein the enclosure is fabricated using electrical resistance welding.

22. The method of claim 19, wherein the enclosure is fabricated using frictional welding.

23. The method of claim 19, wherein the enclosure is fabricated using cold gas dynamic spraying.

24. The method of claim 19, further including the step of using a subtractive fabrication process to achieve a final desired shape.

25. The method of claim 19, further including the steps of:
encapsulating the electronic circuitry in a non-metallic form; and
fabricating the enclosure over the encapsulated electronic circuitry.
